(19) United States
(12) Patent Application Publication
(10) Pub. No.: US 2008/0069668 A1
(43) Pub. Date: Mar. 20, 2008

(54) Semiconductor manufacturing apparatus

(75) Inventor: Young Cheul Lee, Suwon-si (KR)

Correspondence Address: MILLS & ONELLO LLP, ELEVEN BEACON STREET, SUITE 605, BOSTON, MA, 02108, US

(73) Assignee: Samsung Electronics, Co., Ltd., Suwon-si (KR)

(21) Appl. No.: 11/820,818

(22) Filed: Jun. 21, 2007

(30) Foreign Application Priority Data
Sep. 18, 2006 (KR) 1020060090068

(51) Int. Cl. H01L 21/67

(52) U.S. Cl. 414/217

(57) ABSTRACT

A semiconductor manufacturing apparatus includes a chamber having a plurality of stages, on each of which a wafer is placed, separately arranged therein, a common pumping line coupled to the chamber and connected to an area of each of the stages and forming a common passage of air that is pumped out from the areas of the stages, and a divider coupled to at least one of the chamber and the common pumping line and dividing the air being pumped to allow the air to be independently pumped from the respective areas of the stages. Thus, the generation of a process error because the RF reflected power is not stable due to the imbalance in pressure between a plurality of stages in a single chamber can be prevented.

### CROSS-REFERENCE TO RELATED PATENT APPLICATIONS

This application claims the benefit of Korean Patent Application No. 10-2006-0090068, filed on 18 Sep. 2006, in the Korean Intellectual Property Office, the contents of which are incorporated herein in their entirety by reference.

### BACKGROUND OF THE INVENTION

1. Field of the Invention

The present invention relates to a semiconductor manufacturing apparatus, and more particularly, to a semiconductor manufacturing apparatus which can prevent a process error generated due to the unstable RF reflected power generated when a plurality of stages separately support wafers in a chamber.

2. Description of the Related Art

In general, wafers are manufactured as semiconductor devices by repeatedly performing manufacturing process steps such as photolithography, diffusion, etching, chemical vapor deposition, and metal deposition. In the manufacture of a semiconductor device, a predetermined pattern is formed on the wafer using plasma in a chamber in a vacuum state or an alien substance is removed. Accordingly, the semiconductor manufacturing apparatus includes a variety of apparatuses such as an etching apparatus for etching a predetermined pattern on the wafer, an ashing apparatus for removing photoresist coated on the wafer, and a chemical vapor deposition apparatus for depositing chemical substances on the wafer.

An ashing apparatus is used to remove photoresist that remains on the wafer after etching the surface of the wafer is performed. In a typical ashing apparatus, a stage is provided in a chamber so that a wafer is placed on the stage and the inside of the chamber is maintained in a vacuum atmosphere to remove the photoresist on the surface of the wafer by plasma.

However, in order to increase a process efficiency such as an increase in the photoresist removing speed, as shown in FIGS. 1 and 2, an ashing apparatus 101 according to a conventional technology has been introduced in which a pair of stages 115 are provided in a lower chamber 113 so that the surface process of two wafers can be simultaneously performed.

As shown in FIG. 1, in the ashing apparatus 101, the stages 115 are separated a predetermined distance by a partition portion 114 forming an upper wall of the lower chamber 113. As shown in FIG. 2, the stages 115 are connected to each other in the lower portion of the lower chamber 113 where the partition portion 114 is located. A pair of individual pumping lines 123 are installed at an outer bottom surface of the lower chamber 113 to connect to the lower chamber 113. That is, each of the individual pumping lines 123 is installed on the bottom surface of each of the stages 115 to connect to the lower chamber 113. A common pumping line 121 is installed on the central bottom surface of the lower chamber 113 under the partition portion 114 to connect to the lower chamber 113.

The common pumping line 121 and the individual pumping lines 123 are connected to each other in the lower portion of the lower chamber 113 and to a vacuum pump (not shown). As the vacuum pump pumps air inside the lower chamber 113 through the common pumping line 121 and the individual pumping lines 123 as indicated by arrows in FIG. 2, the inside of the lower chamber 113 has a vacuum atmosphere of a particular pressure needed to remove a photoresist layer on a wafer W.

A high frequency power (RF power) is applied to the inside of the lower chamber 113. A high frequency wave in a predetermined frequency range needs to be provided into the lower chamber 113. When a high frequency wave in an appropriate range is not provided, the photoresist remains on the surface of the wafer W or a defect may be created, which works as a major factor to cause degradation in productivity.

In particular, when the photoresist is not removed completely, the wafer W must be ashed again, resulting in unnecessary additional process time such that the overall process time is increased.

In the conventional ashing apparatus 101, as the air is pumped toward the common pumping line 121 from the stages 115 in the lower chamber 113, imbalance in pressure between the stages 115 is generated. Thus, an RF reflected power value increases so that a process error may be generated.

### SUMMARY OF THE INVENTION

To solve the above and/or other problems, the present invention provides a semiconductor manufacturing device which can prevent a process error generated due to the unstable RF reflected power between a plurality of stages in a chamber.

According to an aspect of the present invention, a semiconductor manufacturing apparatus comprises a chamber having a plurality of stages arranged in the chamber, a wafer being placed on each of the stages. A common pumping line is coupled to the chamber and connected to an area of each of the stages and forming a common passage of air that is pumped out from the areas of the stages. A divider is coupled to at least one of the chamber and the common pumping line and dividing the air being pumped to allow the air to be independently pumped from the respective areas of the stages.

In one embodiment, the divider separates the inner space of the chamber for each stage and separates the common pumping line for each stage from an upper end of the common pumping line to a predetermined depth.

In one embodiment, the divider comprises: a main body having a connection hole connecting to the inside of the common pumping line and coupled to an entrance area of the common pumping line in a direction in which the air is pumped; a chamber partition extending upward from an upper surface of the main body and separating the inner space of the chamber and the connection hole for each stage; and a pumping line partition extending downward from a lower surface of the main body and separating the connection hole and the inner space of the common pumping line for each stage.

In one embodiment, the number of the stages is two, a partition portion extending from an upper wall of the chamber toward the pumping line to a predetermined length is further provided between the stages, and an upper end of the chamber partition contacts a lower surface of the partition portion.

In one embodiment, the chamber partition and the pumping line partition have substantially the same sectional shape and a concave circular arc portion is formed at at least one side surface of each of the chamber partition and the pumping line partition.

In one embodiment, the main body has a doughnut shape and the inner diameter of the connection hole is substantially the same as the diameter of the pumping line.

In one embodiment, t plurality of bolt holes to which a plurality of bolts are coupled are separately formed in the main body along an outer circumferential surface, and the main body is coupled to the chamber as the bolts are coupled to a bottom surface of the chamber by penetrating the bolt holes.

The main body, the chamber partition, and the pumping line partition can be integrally formed. In one embodiment, they are integrally formed of aluminum (Al).

Surfaces of the main body, the chamber partition, and the pumping line partition can be anodized.

In one embodiment, the semiconductor manufacturing apparatus further comprises a plurality of individual pumping lines provided at the opposite sides of the common pumping line with respect to each of the stages and forming a passage through which the air is pumped from the areas of the respective stages with the common pumping line.

In one embodiment, the individual pumping lines and the common pumping line are connected to each other.

In one embodiment, the chamber comprises an upper chamber and a lower chamber and the upper chamber is provided corresponding to the stages and coupled to the lower chamber to cover the upper portion of each stage installed in the lower chamber.

In one embodiment, the gas diffuser plate injecting reaction material in a plasma state to the area of each stage is installed in each of the upper chamber.

In one embodiment, the semiconductor manufacturing apparatus is an ashing apparatus.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic perspective view of the lower chamber area of a conventional ashing apparatus.

FIG. 2 is a schematic cross-sectional view taken along line II-II of FIG. 1.

FIG. 3 is a schematic cross-sectional view of an ashing apparatus according to an embodiment of the present invention.

FIG. 4 is a detailed schematic perspective view which illustrates the divider of FIG. 3 coupled to a common pumping line.

FIGS. 5, 6A, 6B and 7 illustrate the divider of FIG. 4 in accordance with the invention.

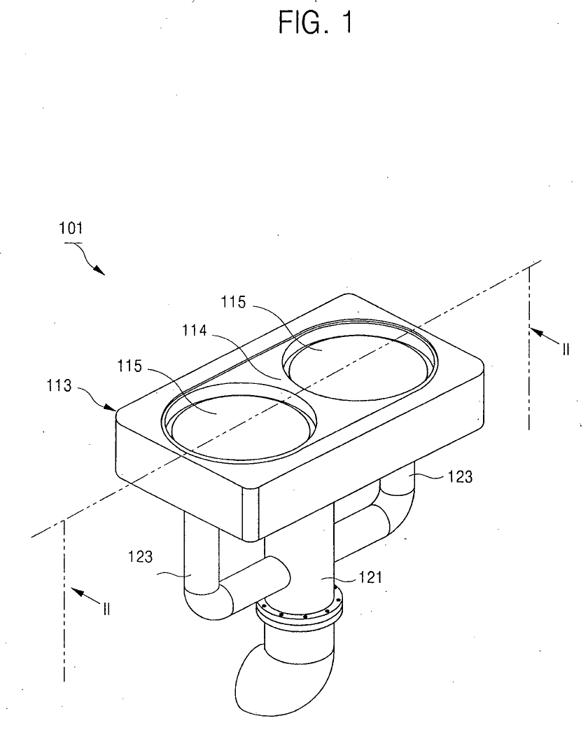

### DETAILED DESCRIPTION OF PREFERRED EMBODIMENTS OF THE INVENTION

A semiconductor manufacturing apparatus according to the present invention can be applied to an ashing apparatus, an etching apparatus, and a chemical vapor deposition apparatus which have a plurality of stages in a chamber. However, for the convenience of description, the following description focuses on an ashing apparatus having a pair of stages in a chamber and simultaneously removing photoresist on wafers placed on the respective stages.

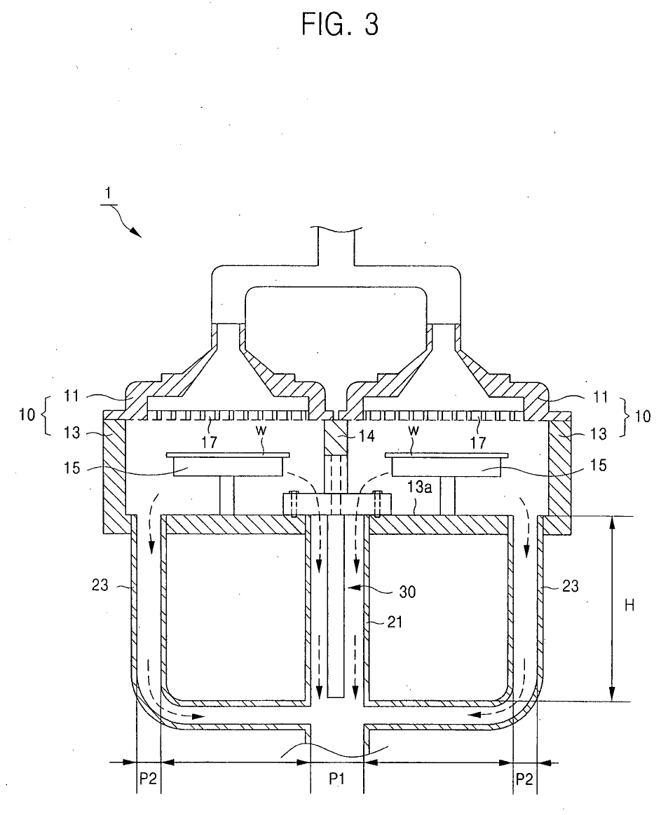

FIG. 3 is a schematic cross-sectional view of an ashing apparatus according to an embodiment of the present invention. Referring to FIG. 3, an ashing apparatus 1 according to an embodiment of the present invention includes a chamber 10, a pair of stages 15 separated from each other with respect to a partition portion 14 in the chamber 10, a pair of gas diffuser plates 17 arranged above the stages 15 and coupled to the chamber 10, a pair of individual pumping lines 23 coupled to the outer areas of a bottom surface 13a of the chamber 10, and a divider 30 coupled to the chamber 10 and a common pumping line 21.

The surface of each wafer W is processed inside the chamber 10. During the ashing process, a vacuum atmosphere is formed in the chamber 10. When a high frequency (RF) power is applied to the chamber 10 a reaction gas is converted to a reaction material (radical) in a plasma state so that the photoresist on the surface of the wafer W is removed.

The chamber 10 includes two upper chambers 11 to which plasma is supplied from above and two lower chambers 13 having the stages 15 installed under the two upper chambers 11. Each of the two upper chambers 11 supplies the RF power from an RF power supply source (not shown) such that the reaction gas can be supplied to the lower chambers 13 in a plasma state. The gas diffuser plates 17 coupled to the upper chambers 11 inject the reaction material in a plasma state to the stages 15. A plurality of holes is formed in each of the gas diffuser plates 17 so that the reaction material in a plasma state can be uniformly injected onto the surface of the wafer W.

In the present embodiment, the upper chambers 11 are respectively manufactured in a quartz dome shape and cover the upper portion of the stages 15 of the lower chambers 13. That is, the upper chambers 11 are open from the lower chambers 13 to place the wafers W on the stages 15 in the lower chambers 13 or remove the wafers from the lower chambers 13. Also, the upper chambers 11 are closed to the lower chambers 13 to maintain the inside of the chamber 10 in a vacuum atmosphere during the ashing process.

In the lower chambers 13, the stages 15 are separately arranged with respect to the partition portion 14 in the chamber 10. The wafer W is placed on each of the stages 15. The common pumping line 21 and the individual pumping lines 23 are coupled to the bottom surface 13a of the lower chambers 13.

The common pumping line 21 is coupled to the bottom surface 13a of the lower chambers 13 under the partition portion 14, that is, in the middle area between the stages 15. The common pumping line 21 forms a passage of air pumped in each of the stages 15 to vacuumize the inside of the chamber 10. That is, when pumping starts to vacuumize the inside of the chamber 10, as indicted by arrows in FIG. 3, the air existing in the outer side of the stages 15 is pumped out through the individual pumping lines 23 while the air between the stages 15 is pumped out through the common pumping lines 21.

The diameter P1 of the common pumping line 21 is greater than the diameter P2 of each of the individual pumping lines 23. In the present embodiment, the diameter P1 and length H of the common pumping line 21 are respectively about 100 mm and about 300 mm. The common pumping line 21 and the individual pumping lines 23 are connected to each other. A vacuum pump (not shown) is coupled to a lower portion of the chamber 10 where the common pumping line 21 and the individual pumping lines 23 are connected. Thus, the respective portions of the stages 15 in the chamber 10 can be pumped with a single vacuum pump.

The individual pumping lines 23 are coupled to the outer areas of the bottom surface 13a of the lower chambers 13, that is, areas where the stages 15 are located. The individual pumping lines 23 function as individual pumping passages to vacuumize the inside of the chamber 10 where the stages 15 are located. In the present embodiment, the individual pumping lines 23 are manufactured to have a diameter P2 of 50 mm. As described above, the individual pumping lines 23 are connected to the common pumping line 21 under the bottom surface 13a of the lower chambers 13. The vacuum pump is coupled from underneath to the portion where the individual pumping lines 23 are connected to the common pumping line 21.

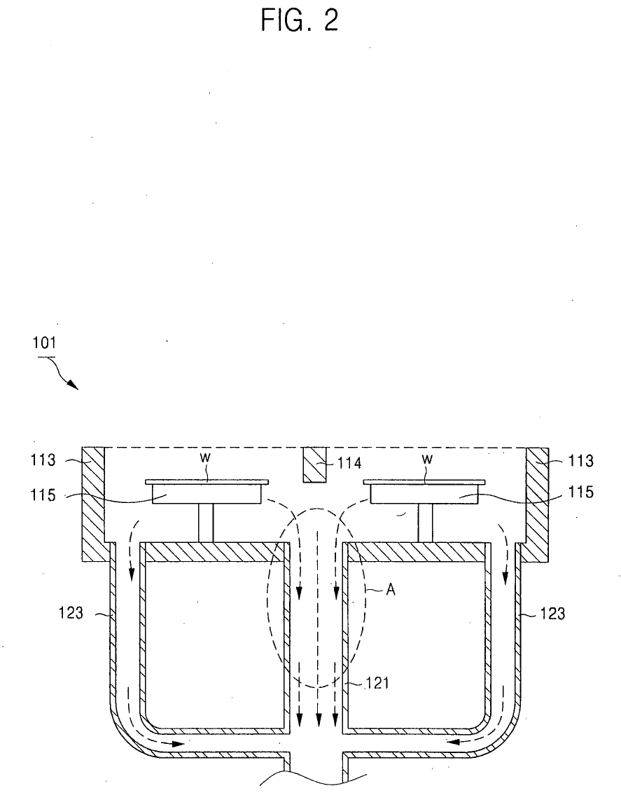

The divider 30 is coupled to the chamber 10 and the common pumping line 21 and separates the air pumped from each area of the stages 15. The divider 30 separates the chamber 10 and the common pumping line 21 to be substantially equal so that the air in the areas of the stages 15 can be independently pumped to a predetermined depth of the bottom surface 13a of the lower chamber 13. Thus, the chamber 10 is divided into two parts by the divider 30. That is, when the air of the inside of the chamber 10 is pumped out through the common pumping line to make a vacuum atmosphere, since the air pumped toward the area analogous to area A of FIG. 2 can be equally divided by the divider 30 to reduce interference between the streams of pumped air from opposite sides of the lower chamber 14, the generation of a process error generated when the RF reflected power is not stable due to the imbalance in the pressure between the stages 15 can be prevented.

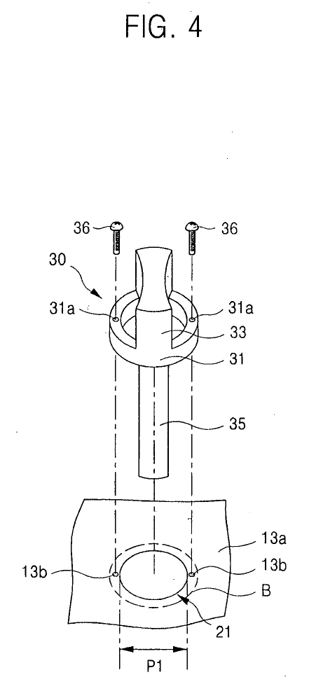

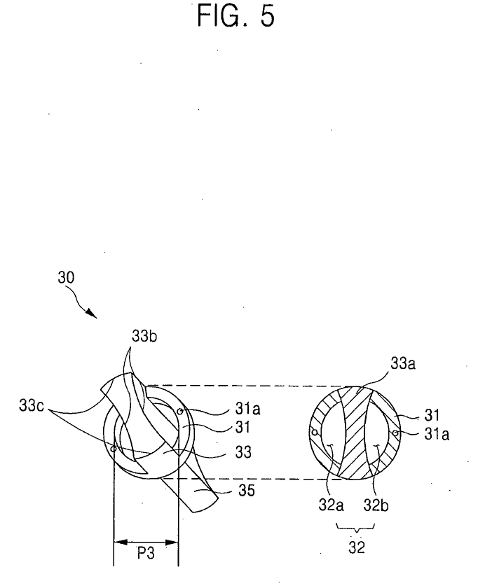

FIG. 4 shows a configuration in which the divider 30 of FIG. 3 is coupled to a common pumping line. FIGS. 5, 6A, 6B and 7 illustrate the divider of FIG. 4. Referring to FIGS. 4, 5, 6A, 6B and 7, the divider 30 includes a main body 31, a chamber partition 33 coupled to the chamber 10 to separate the chamber 10, and a pumping line partition 35 separating the common pumping line 21.

The main body 31, as shown in FIG. 4, is coupled to an entrance area B of the common pumping line 21 provided in an area of the bottom surface 13a of the lower chambers 13. In the present embodiment, the main body 31 is coupled to the common pumping line 21 by coupling a bolt 36 to a bolt hole 31a formed in the main body 31 and a bolt coupling hole 13b formed in the entrance area B of the common pumping line 21.

The main body 31, as shown in FIG. 5, has a connection hole 32 connected to the inside of the common pumping line 21. The connection hole 32 is formed in two parts including a first connection hole 32a and a second connection hole 32b to independently separate the stages 15. In the present embodiment, the first and second connection holes 32a and 32b have the same size. When the number of the stages 15 is three or more, the connection hole 32 can be divided into three or more individual connection holes.

The main body 31 according to the present embodiment has a doughnut shape and the inner diameter P3 of the main body 31 is substantially the same as the diameter P1 of the common pumping line 21, such that the main body 31 is coupled to the common pumping line 21 so that the connection hole 32 substantially equally separates or divides the common pumping line 21.

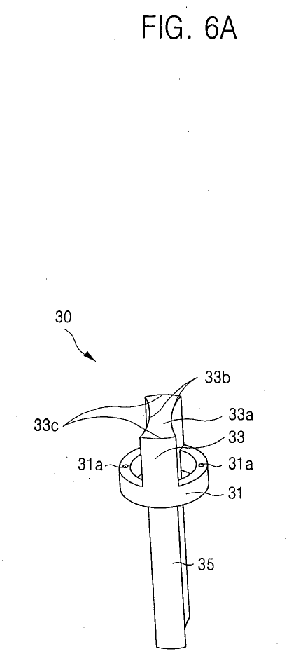

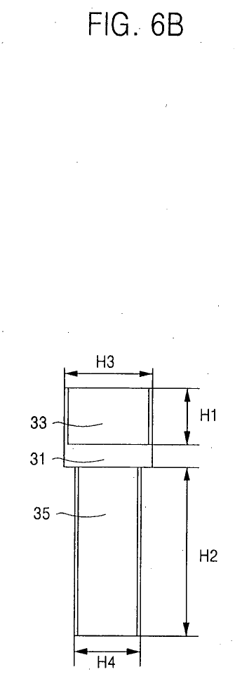

The chamber partition 33 extends upward from the upper surface of the main body 31 to separate the inner space of the chamber 10 into parts corresponding to the number of the stages 15. In the present embodiment, the chamber partition 33, as shown in FIG. 4, substantially separates the chamber 10 into two chambers divided by the partition portion 14. A section 33a of the chamber partition 33, as shown in FIGS. 5, 6A, and 6B, has a shape such that a concave circular arc portion 33b is symmetrically formed at opposite sides thereof and a convex circular arc portion 33c is symmetrically formed at the other opposite sides thereof.

The section 33a of the chamber partition 33 has a shape corresponding to the section of the partition portion 14 of the chamber 10. Thus, as shown in FIG. 3, the chamber partition 33 is coupled to the lower surface of the partition portion 14 to contact each other so that the chamber 10 is divided into two parts by the chamber partition 33.

The height H of the chamber partition 33 can be adjusted according to the distance from the bottom surface 13a of the lower chambers 13 to the partition portion 14. The width H3 of the chamber partition 33 can be adjusted to have a size to divide the chamber 10 into a predetermined number of parts corresponding to the number of the stages 15.

The pumping line partition 35 extends downward from the lower surface of the main body 31 to divide the inner space of the common pumping line 21 into a predetermined number of parts corresponding to the number of stages 15, that is, two parts in the present embodiment. The height H2 of the pumping line partition 35 can be determined within a range not more than 300 mm that is the length H of the common pumping line 21. In the present embodiment, as shown in FIG. 3, the height H2 of the pumping line partition 35 extends to a point where the common pumping line 21 and the individual pumping lines 23 are connected to each other.

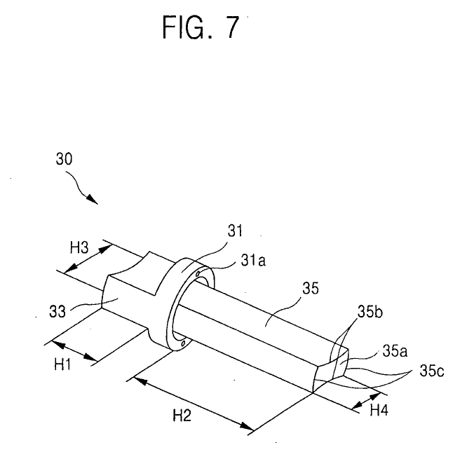

The shape of the section 35a of the pumping line partition 35, as shown in FIG. 7, is substantially the same as the shape of the section 33a of the chamber partition 33 so that a concave circular arc portion 35b is symmetrically formed at opposite sides thereof and a convex circular arc portion 35c is symmetrically formed at the other opposite sides thereof.

The concave circular arc portion 35b having a curved shape makes the flow of air pumped out through the common pumping line 21 smooth. The convex shape of the convex circular arc portion 35c makes the pumping line partition 35 stably coupled to the inner wall of the common pumping line 21. Thus, the width H4 of the pumping line partition 35 in the present embodiment has substantially the same size as the diameter P1 of the common pumping line 21.

In the present embodiment, the divider 30 is integrally manufactured of aluminum (Al) and the surface of the divider 30 is anodized. That is, the divider 30 can be formed of an aluminum material that is easy to manufacture and, considering friction with the air and the reaction by the radial material in the chamber 10, the surface of the divider 30 is processed such that an oxide surface is formed in an anodizing method to reinforce anti-abrasion and strength.

Since the divider 30 configured as above is coupled to the chamber 10 and the common pumping line 21 to separate the areas of the stages 15 and the air pumped out from the stages 15, when a vacuum atmosphere is formed as the air in the chamber 10 is pumped out through the common pumping line 21, the conventional problems that the imbalance in pressure generated in the area A of FIG. 2 and the increase of a reflected wave due to the RF noise can be solved.

Thus, according to the invention, since the flow of the air pumped out through the common pumping line 21 is equally divided by the divider, the generation of a process error generated by the unstable RF reflected power due to the imbalance in the pressure between the stages 15 can be prevented.

The operation of the ashing apparatus according to the present embodiment will now be described with reference to the drawings. First, as the upper chambers 11 are open from the lower chambers 13, the wafers W are loaded on each of the stages 15 provided in the lower chambers 13. When the wafers W are loaded on each of the stages 15, the upper chambers 11 are closed to the lower chambers 13 forming a seal state. As the upper chambers 11 and the lower chambers 13 are sealed, to form a vacuum atmosphere having a predetermined pressure in the chamber 10 isolated from the outside, the vacuum pump starts pumping the air in the chamber 10 out through the common pumping line 21 and the individual pumping lines 23.

The air in the outer area of the stages 15 is pumped out through the individual pumping lines 23 as indicated by the arrows in FIG. 3. However, the air in the areas of the stages 15 and between the stages 15 is pumped through the common pumping line 21.

The divider 30 coupled to the common pumping line 21 substantially equally separates the chamber 10 and the common pumping line 21 such that the air in the areas of the stages 15 are not mixed together and are independently pumped. In the present embodiment, the common pumping line 21 is divided by the divider 30 into the connection holes 32a and 32b having the same size, as shown in FIG. 5.

Thus, since the air flowing from the inside of the chamber 10 through the common pumping line 21 is pumped out through the connection holes 32a and 32b by being equally divided by the divider 30, the imbalance of pressure generated between the stages 15 can be solved. Accordingly, the inside of the chamber 10 is a vacuum atmosphere of a predetermined pressure needed to remove the photoresist layer on the wafer W.

RF power is applied to the inside of the chamber 10. A high frequency wave is a preset frequency and provided into the chamber 10. When the normal high frequency wave is not provided, photoresist may remain on the surface of the wafer W or a defect may occur.

However, since the divider 30 according to the present embodiment is coupled to the chamber 10 and the common pumping line 21 and separates the flow of the air pumped out from the areas of the stages 15, the problem that the RF reflected power is instable due to the imbalance in the pressure between the stages 15 is solved. Also, a high frequency wave in an appropriate range can be provided into the chamber 10 so that a process error can be remarkably prevented.

In the above-described embodiment, the main body, the chamber partition, and the pumping line partition are integrally manufactured. However, these elements can be assembled after being separately manufactured.

Also, in the above-described embodiment, the present invention is described in terms of an ashing apparatus having two stages. However, the technical concept of the present invention can be applied to an ashing apparatus having three or four stages. In addition to the ashing apparatus, when a plurality of stages are provided in a chamber, the technical concept of the present invention can be applied to an etching apparatus or a chemical vapor deposition apparatus, or other similar apparatus.

While this invention has been particularly shown and described with reference to preferred embodiments thereof, it will be understood by those skilled in the art that various changes in form and details may be made therein without departing from the spirit and scope of the invention as defined by the appended claims.

As described above, according to the present invention, the generation of a process error because the RF reflected power is not stable due to the imbalance in pressure between a plurality of stages in a single chamber can be prevented. Accordingly, equipment operation rate and productivity are improved.

What is claimed is:

1. A semiconductor manufacturing apparatus, comprising:
a chamber having a plurality of stages arranged in the chamber, a wafer being placed on each of the stages;
a common pumping line coupled to the chamber and connected to an area of each of the stages and forming a common passage of air that is pumped out from the areas of the stages; and
a divider coupled to at least one of the chamber and the common pumping line and dividing the air being pumped to allow the air to be independently pumped from the respective areas of the stages.

2. The semiconductor manufacturing apparatus of claim 1, wherein the divider separates inner space of the chamber for each stage and separates the common pumping line for each stage from an upper end of the common pumping line to a predetermined depth.

3. The semiconductor manufacturing apparatus of claim 2, wherein the divider comprises:
a main body having a connection hole connecting to the inside of the common pumping line and coupled to an entrance area of the common pumping line in a direction in which the air is pumped;
a chamber partition extending upward from an upper surface of the main body and separating the inner space of the chamber and the connection hole for each stage; and
a pumping line partition extending downward from a lower surface of the main body and separating the connection hole and the inner space of the common pumping line for each stage.

4. The semiconductor manufacturing apparatus of claim 3, wherein a quantity of the stages is two, a partition portion extending from an upper wall of the chamber toward the pumping line to a predetermined length is further provided between the stages, and an upper end of the chamber partition contacts a lower surface of the partition portion.

5. The semiconductor manufacturing apparatus of claim 3, wherein the chamber partition and the pumping line partition have substantially the same sectional shape and a concave circular arc portion is formed at least one side surface of each of the chamber partition and the pumping line partition.

6. The semiconductor manufacturing apparatus of claim 3, wherein the main body has a doughnut shape and the inner diameter of the connection hole is substantially the same as the diameter of the pumping line.

7. The semiconductor manufacturing apparatus of claim 3, wherein a plurality of bolt holes to which a plurality of bolts are coupled are separately formed in the main body along an outer circumferential surface and the main body is coupled to the chamber by bolts coupled to a bottom surface of the chamber by penetrating the bolt holes.

8. The semiconductor manufacturing apparatus of claim 3, wherein the main body, the chamber partition, and the pumping line partition are integrally formed.

9. The semiconductor manufacturing apparatus of claim 3, wherein the main body, the chamber partition, and the pumping line partition are integrally formed of aluminum (Al).

10. The semiconductor manufacturing apparatus of claim 9, wherein surfaces of the main body, the chamber partition, and the pumping line partition are anodized.

11. The semiconductor manufacturing apparatus of claim 1, further comprising a plurality of individual pumping lines provided at opposite sides of the common pumping line with respect to each of the stages and forming a passage through which the air is pumped from the areas of the respective stages with the common pumping line.

12. The semiconductor manufacturing apparatus of claim 11, wherein the individual pumping lines and the common pumping line are connected to each other.

13. The semiconductor manufacturing apparatus of claim 1, wherein the chamber comprises an upper chamber and a lower chamber, and the upper chamber is provided corresponding to the stages and coupled to the lower chamber to cover the upper portion of each stage installed in the lower chamber.

14. The semiconductor manufacturing apparatus of claim 13, wherein a gas diffuser plate injecting reaction material in a plasma state to the area of each stage is installed in each upper chamber.

15. The semiconductor manufacturing apparatus of claim 13, wherein the semiconductor manufacturing apparatus is an ashing apparatus.
